(19) United States
(12) Patent Application Publication
(10) Pub. No.: US 2010/0289043 A1
(43) Pub. Date: Nov. 18, 2010

(54) HIGH LIGHT EXTRACTION EFFICIENCY LIGHT EMITTING DIODE (LED) THROUGH MULTIPLE EXTRACTORS

(75) Inventors: David J. F. Aurelien, Paris (FR); Claude C. A. Weisbuch, Paris (FR); Akihiko Murai, Yao (JP); Steven P. DenBaars, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/940,848

(22) Filed: Nov. 15, 2007

Related U.S. Application Data
(60) Provisional application No. 60/866,014, filed on Nov. 15, 2006.
(60) Provisional application No. 60/883,977, filed on Jan. 8, 2007.

(51) Int. Cl. H01L 33/58; H01L 21/28

(52) U.S. Cl. 257/98; 438/29; 257/E33.067; 257/E21.158

(57) ABSTRACT

An (Al,In,Ga)N and ZnO direct wafer bonded light emitting diode (LED), combined with a second light extractor acting as an additional light extraction method. This second light extraction method aims at extracting the light which has not been extracted by the ZnO structure, and more specifically the light which is trapped in the (Al,In,Ga)N layer. This second method is suited for light extraction from thin films, using surface patterning or texturing, or a photonic crystal acting as a diffraction grating. The combination of both the ZnO structure and the second light extraction method enables most of the emitted light from the LED to be extracted. In a more general extension of the present invention, the ZnO structure can be replaced by another material in order to achieve additional light extraction. In another extension, the (Al,In,Ga)N layer can be replaced by structures comprising other materials compositions, in order to achieve additional light extraction.

### CROSS-REFERENCE TO RELATED APPLICATIONS

This application claims the benefit under 35 U.S.C. Section 119(e) of the following co-pending and commonly-assigned U.S. patent applications:

U.S. Provisional Application Ser. No. 60/866,014, filed on Nov. 15, 2006, by Steven P. DenBaars, Aurelien J. F. David, and Claude C. A. Weisbuch, entitled “HIGH LIGHT EXTRACTION EFFICIENCY LIGHT EMITTING DIODE (LED) (LED) THROUGH MULTIPLE EXTRACTORS,” attorneys' docket number 30794.191-US-P1 (2007-047-1); and

U.S. Provisional Application Ser. No. 60/883,977, filed on Jan. 8, 2007, by Aurelien J. F. David, Claude C. A. Weisbuch, Akihiko Murai and Steven P. DenBaars, entitled “HIGH LIGHT EXTRACTION EFFICIENCY LIGHT EMITTING DIODE (LED) (LED) THROUGH MULTIPLE EXTRACTORS,” attorneys' docket number 30794.191-US-P2 (2007-047-2);

which applications are incorporated by reference herein.

This application is related to the following co-pending and commonly-assigned applications:

U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C. Section 365(c) of PCT Application Serial No. US2003/03921, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 11/054,271, filed on Feb. 9, 2005, by Rajat Sharma, P. Morgan Pattison, John F. Kaeding, and Shuji Nakamura, entitled “SEMICONDUCTOR LIGHT EMITTING DEVICE,” attorney's docket number 30794.112-US-01 (2004-208);

U.S. Utility application Ser. No. 10/938,704, filed on Sep. 10, 2004, by Carole Schwach, Claude C. A. Weisbuch, Steven P. DenBaars, Henri Benisty and Shuji Nakamura, entitled “WHITE, SINGLE OR MULTICOLOR LED BY RECYCLING GUIDED MODES,” attorney's docket number 30794.115-US-01 (2004-064);

U.S. Utility application Ser. No. 11/175,761, filed on Jul. 6, 2005, by Akihiko Murai, Lee McCarthy, Umesh K. Mishra and Steven P. DenBaars, entitled “METHOD FOR WAFER BONDING (Al,In,Ga)N and Zn(S,Se) FOR OPTOELECTRONICS APPLICATIONS,” attorney's docket number 30794.116-US-U1 (2004-455), which application claims the benefit under 35 U.S.C. Section 119(e) of U.S. Provisional Application Ser. No. 60/585,673, filed Jul. 6, 2004, by Akihiko Murai, Lee McCarthy, Umesh K. Mishra and Steven P. DenBaars, entitled “METHOD FOR WAFER BONDING (Al,In,Ga)N and Zn(S,Se) FOR OPTOELECTRONICS APPLICATIONS,” attorney's docket number 30794.116-US-P1 (2004-455-1);

U.S. Utility application Ser. No. 11/067,957, filed Feb. 28, 2005, by Claude C. A. Weisbuch, Aurelien J. F. David, James S. Speck and Steven P. DenBaars, entitled “HORIZONTAL EMITTING, VERTICAL EMITTING, BEAM SHAPED, DISTRIBUTED FEEDBACK (DFB) LASERS BY GROWTH OVER A PATTERNED SUBSTRATE,” attorneys' docket number 30794.121-US-01 (2005-144-1);

U.S. Utility application Ser. No. 11/067,910, filed Feb. 28, 2005, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-1);

U.S. Utility application Ser. No. 11/067,956, filed Feb. 28, 2005, by Aurelien J. F. David, Claude C. A Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1);

U.S. Utility application Ser. No. 11/403,624, filed Apr. 13, 2006, by James S. Speck, Troy J. Baker and Benjamin A. Haskell, entitled “WAFER SEPARATION TECHNIQUE FOR THE FABRICATION OF FREE-STANDING (AL,IN,GA)N WAFERS,” attorneys' docket number 30794.131-US-U1 (2005-482-2), which application claims the benefit under 35 U.S.C. Section 119(e) of U.S. Provisional Application Ser. No. 60/670,810, filed Apr. 13, 2005, by James S. Speck, Troy J. Baker and Benjamin A. Haskell, entitled “WAFER SEPARATION TECHNIQUE FOR THE FABRICATION OF FREE-STANDING (AL,IN,GA)N WAFERS,” attorneys' docket number 30794.131-US-P1 (2005-482-1);

U.S. Utility application Ser. No. 11/403,288, filed Apr. 13, 2006, by James S. Speck, Benjamin A. Haskell, P. Morgan Pattison and Troy J. Baker, entitled “ETCHING TECHNIQUE FOR THE FABRICATION OF THIN (AL,IN,GA)N LAYERS,” attorneys' docket number 30794.132-US-U1 (2005-509-2), which application claims the benefit under 35 U.S.C. Section 119(e) of U.S. Provisional Application Ser. No. 60/670,790, filed Apr. 13, 2005, by James S. Speck, Benjamin A. Haskell, P. Morgan Pattison and Troy J. Baker, entitled “ETCHING TECHNIQUE FOR THE FABRICATION OF THIN (AL,IN,GA)N LAYERS,” attorneys' docket number 30794.132-US-P1 (2005-509-1);

U.S. Utility application Ser. No. 11/454,691, filed on Jun. 16, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDING STRUCTURE FOR OPTOELECTRONIC APPLICATIONS AND ITS FABRICATION METHOD,” attorneys' docket number 30794.134-US-U1 (2005-536-4), which application claims the benefit under 35 U.S.C. Section 119(e) of U.S. Provisional Application Ser. No. 60/691,710, filed on Jun. 17, 2005, by Akihiko Murai, Christina Ye Chen, Lee S. McCarthy, Steven P. DenBaars, Shuji Nakamura, and Umesh K. Mishra, entitled “(Al,Ga,In)N AND ZnO DIRECT WAFER BONDING STRUCTURE FOR OPTOELECTRONIC APPLICATIONS, AND ITS FABRICATION METHOD,” attorneys' docket number 30794.134-US-P1 (2005-536-1), U.S. Provisional Application Ser. No. 60/732,319, filed on Nov. 1, 2005, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDED STRUCTURE FOR OPTOELECTRONIC APPLICATIONS, AND ITS FABRICATION METHOD,” attorneys' docket number 30794.134-US-P2 (2005-536-2), and U.S. Provisional Application Ser. No. 60/764,881, filed on Feb. 3, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDED STRUCTURE FOR OPTOELECTRONIC APPLICATIONS AND ITS FABRICATION METHOD,” attorneys' docket number 30794.134-US-P3 (2005-536-3);

U.S. Utility application Ser. No. 11/251,365 filed Oct. 14, 2005, by Frederic S. Diana, Aurelien J. F. David, Pierre M. Petroff, and Claude C. A. Weisbuch, entitled “PHOTONIC STRUCTURES FOR EFFICIENT LIGHT EXTRACTION AND CONVERSION IN MULTI-COLOR LIGHT EMITTING DEVICES,” attorneys' docket number 30794.142-US-01 (2005-534-1);

U.S. Utility application Ser. No. 11/643,148, filed Dec. 4, 2006, Claude C. A. Weisbuch and Shuji Nakamura, entitled “IMPROVED HORIZONTAL EMITTING, VERTICAL EMITTING, BEAM SHAPED, DFB LASERS FABRICATED BY GROWTH OVER PATTERNED SUBSTRATE WITH MULTIPLE OVERGROWTH,” attorneys' docket number 30794.143-US-U1 (2005-721-2), which application claims the benefit under 35 U.S.C. Section 119(e) of U.S. Provisional Application Ser. No. 60/741,935, filed Dec. 2, 2005, Claude C. A. Weisbuch and Shuji Nakamura, entitled “IMPROVED HORIZONTAL EMITTING, VERTICAL EMITTING, BEAM SHAPED, DFB LASERS FABRICATED BY GROWTH OVER PATTERNED SUBSTRATE WITH MULTIPLE OVERGROWTH,” attorneys' docket number 30794.143-US-P1 (2005-721-1);

U.S. Utility application Ser. No. 11/593,268, filed on Nov. 6, 2006, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-U1 (2006-271-2), which application claims the benefit under 35 U.S.C. Section 119(e) of U.S. Provisional Application Ser. No. 60/734,040, filed on Nov. 4, 2005, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-P1 (2006-271-1);

U.S. Utility application Ser. No. 11/608,439, filed on Dec. 8, 2006, by Steven P. DenBaars, Shuji Nakamura and James S. Speck, entitled “HIGH EFFICIENCY LIGHT EMITTING DIODE (LED),” attorneys' docket number 30794.164-US-U1 (2006-318-3), which application claims the benefit under 35 U.S.C. Section 119(e) of U.S. Provisional Application Ser. No. 60/764,975, filed on Feb. 3, 2006, by Steven P. DenBaars, Shuji Nakamura and James S. Speck, entitled “HIGH EFFICIENCY LIGHT EMITTING DIODE (LED),” attorneys' docket number 30794.164-US-P2 (2006-318-2), and U.S. Provisional Application Ser. No. 60/748,480, filed on Dec. 8, 2005, by Steven P. DenBaars, Shuji Nakamura and James S. Speck, entitled “HIGH EFFICIENCY LIGHT EMITTING DIODE (LED),” attorneys' docket number 30794.164-US-P1 (2006-318-1);

U.S. Utility application Ser. No. 11/676,999, filed on Feb. 24, 2007, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-U1 (2006-422-2), which application claims the benefit under 35 U.S.C. Section 119(e) of U.S. Provisional Application Ser. No. 60/774,467, filed on Feb. 17, 2006, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-P1 (2006-422-1);

U.S. Utility patent application Ser. No. ______, filed on Nov. 15, 2007, by Claude C. A. Weisbuch, James S. Speck and Steven P. DenBaars entitled “HIGH EFFICIENCY WHITE, SINGLE OR MULTI-COLOUR LED BY INDEX MATCHING STRUCTURES,” attorney's docket number 30794. 196-US-U1 (2007-114-2), which application claims the benefit under 35 U.S.C. Section 119(e) of U.S. Provisional Patent Application Ser. No. 60/866,026, filed on Nov. 15, 2006, by Claude C. A. Weisbuch, James S. Speck and Steven P. DenBaars entitled “HIGH EFFICIENCY WHITE, SINGLE OR MULTI-COLOUR LED BY INDEX MATCHING STRUCTURES,” attorney's docket number 30794. 196-US-P1 (2007-114-1);

U.S. Utility patent application Ser. No. ______, filed on Nov. 15, 2007, by Aurelien J. F. David, Claude C. A. Weisbuch, Steven P. DenBaars and Stacia Keller, entitled “HIGH LIGHT EXTRACTION EFFICIENCY LED WITH EMITTERS WITHIN STRUCTURED MATERIALS,” attorney's docket number 30794. 197-US-U1 (2007-113-2), which application claims the benefit under 35 U.S.C. Section 119(e) of U.S. Provisional Patent Application Ser. No. 60/866,015, filed on Nov. 15, 2006, by Aurelien J. F. David, Claude C. A. Weisbuch, Steven P. DenBaars and Stacia Keller, entitled “HIGH LIGHT EXTRACTION EFFICIENCY LED WITH EMITTERS WITHIN STRUCTURED MATERIALS,” attorney's docket number 30794. 197-US-P1 (2007-113-1);

U.S. Utility patent application Ser. No. ______, filed on Nov. 15, 2007, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-U1 (2007-161-2), which application claims the benefit under 35 U.S.C. Section 119(e) of U.S. Provisional Patent Application Ser. No. 60/866,027, filed on Nov. 15, 2006, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-P1 (2007-161-1);

U.S. Utility patent application Ser. No. ______, filed on Nov. 15, 2007, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-U1 (2007-270-2), which application claims the benefit under 35 U.S.C. Section 119(e) of U.S. Provisional Patent Application Ser. No. 60/866,024, filed on Nov. 15, 2006, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-P1 (2007-270-1);

U.S. Utility patent application Ser. No. ______, filed on Nov. 15, 2007, by Steven P. DenBaars, Shuji Nakamura and Hisashi Masui, entitled “HIGH LIGHT EXTRACTION EFFICIENCY SPHERE LED,” attorney's docket number 30794.204-US-U1 (2007-271-2), which application claims the benefit under 35 U.S.C. Section 119(e) of U.S. Provisional Patent Application Ser. No. 60/866,025, filed on Nov. 15, 2006, by Steven P. DenBaars, Shuji Nakamura and Hisashi Masui, entitled “HIGH LIGHT EXTRACTION EFFICIENCY SPHERE LED,” attorney's docket number 30794.204-US-P1 (2007-271-1);

U.S. Utility patent application Ser. No. ______, filed on Nov. 15, 2007, by Shuji Nakamura and Steven P. DenBaars, entitled “STANDING TRANSPARENT MIRROR-LESS (STML) LIGHT EMITTING DIODE,” attorney's docket number 30794.205-US-U1 (2007-272-2), which application claims the benefit under 35 U.S.C. Section 119(e) of U.S. Provisional Patent Application Ser. No. 60/866,017, filed on Nov. 15, 2006, by Shuji Nakamura and Steven P. DenBaars, entitled “STANDING TRANSPARENT MIRROR-LESS (STML) LIGHT EMITTING DIODE,” attorney's docket number 30794.205-US-P1 (2007-272-1); and

U.S. Utility patent application Ser. No. ______, filed on Nov. 15, 2007, by Steven P. DenBaars, Shuji Nakamura and James S. Speck, entitled “TRANSPARENT MIRROR-LESS (TML) LIGHT EMITTING DIODE,” attorney's docket number 30794.206-US-U1 (2007-273-2), which application claims the benefit under 35 U.S.C. Section 119(e) of U.S. Provisional Patent Application Ser. No. 60/866,023, filed on Nov. 15, 2006, by Steven P. DenBaars, Shuji Nakamura and James S. Speck, entitled “TRANSPARENT MIRROR-LESS (TML) LIGHT EMITTING DIODE,” attorney's docket number 30794.206-US-P1 (2007-273-1);

which applications are incorporated by reference herein.

### BACKGROUND OF THE INVENTION

1. Field of the Invention

This invention relates to light emitting diode (LED) light extraction for optoelectronic applications.

2. Description of the Related Art

(Note: This application references a number of different publications and patents as indicated throughout the specification by one or more reference numbers within brackets, e.g., [x]. A list of these different publications and patents ordered according to these reference numbers can be found below in the section entitled “References.” Each of these publications and patents is incorporated by reference herein.)

A number of publications and patents are devoted to the issue of light extraction from the light-emitting semiconductor material. One can use effects relying on geometrical optics such as pyramids, outcoupling tapers or textured surfaces [8-14]. One can also use effects relying on wave optics such as microcavity resonances or photonic crystal extraction [15-18]. Special growth techniques such as pendeo or cantilever growths [19,20] and lateral epitaxial overgrowth [21,22] may also be used.

For more recent advances in the field of LED extraction, little is published but the concepts for light extraction by photonic crystal effects or Zinc Oxide (ZnO) pyramids are well described in the cross-referenced patents listed above.

### SUMMARY OF THE INVENTION

The present invention describes an (Al,In,Ga)N and ZnO direct wafer bonded light emitting diode (LED), combined with an additional light extraction method. This additional light extraction method aims at extracting the light which has not been extracted by the ZnO structure, and more specifically the light which is trapped in the (Al,In,Ga)N layer. This additional light extraction method is suited for light extraction from thin films, using surface patterning or texturing, or a photonic crystal acting as a diffraction grating. The combination of both the ZnO structure and the additional light extraction method enables most of the emitted light to be extracted. In a more general extension of the present invention, the ZnO structure can be replaced by another material in order to achieve additional light extraction. In another extension, the (Al,In,Ga)N layer can be replaced by light emitting structures comprising other material compositions, in order to achieve additional light extraction.

### BRIEF DESCRIPTION OF THE DRAWINGS

FIGS. 1a and 1b are schematic cross-sections of an (Al,Ga,In)N and ZnO direct wafer-bonded LED structure, shown in FIG. 1a, and combined, or embedded, in a shaped light extractor such as a plastic lens, illustrated in FIG. 1b.

FIG. 2 is a schematic cross-section of an (Al,Ga,In)N and ZnO direct wafer-bonded LED structure where the substrate has been removed.

FIG. 3 shows the calculated angular distribution of the internally emitted LED light before extraction.

FIG. 4 is a general schematic of the invention disclosed in this patent, showing a ZnO pyramid extractor associated with another (second) extractor.

FIG. 5 is a schematic cross-section of an (Al,Ga,In)N and ZnO direct wafer-bonded LED structure, where the (Al,Ga,In)N layer has been patterned with cusps prior to the ZnO bonding.

FIG. 6 is a schematic cross-section of an (Al,Ga,In)N and ZnO direct wafer-bonded LED structure where the substrate has been removed, and where the (Al,Ga,In)N has some random roughening or structuring.

FIG. 7 is a schematic cross-section of an (Al,Ga,In)N and ZnO direct wafer-bonded LED structure, where the (Al,Ga,In)N layer has been patterned as a photonic crystal before the ZnO bonding.

FIG. 8 is a schematic cross-section of an (Al,Ga,In)N and ZnO direct wafer-bonded LED structure, where the (Al,Ga,In)N layer has been patterned with cusps prior to the ZnO bonding, the cusps being filled by a phosphor material.

FIG. 9 is a schematic cross-section of an (Al,Ga,In)N and ZnO direct wafer-bonded LED structure, where the upper part of the (Al,Ga,In)N layer has been obtained through lateral epitaxial overgrowth (LEO).

FIG. 10 is a schematic cross-section of an (Al,Ga,In)N and ZnO direct wafer-bonded LED structure, where the upper part of the (Al,Ga,In)N layer has been obtained through pendeo epitaxy, and where air inclusions are embedded in the layer above the patterned mask material.

FIG. 11 is a schematic cross-section of an (Al,Ga,In)N and ZnO direct wafer-bonded LED structure, where the upper part of the (Al,Ga,In)N layer has been obtained through pendeo epitaxy above an etched pattern, and where air inclusions are embedded in the (Al,Ga,In)N layer.

FIG. 12 is a schematic cross-section of an (Al,Ga,In)N and ZnO direct wafer-bonded LED structure, where the upper part of the (Al,Ga,In)N layer has been obtained through pendeo epitaxy above a pattern of damaged surface regions, and where air inclusions are embedded in the (Al,Ga,In)N layer.

FIG. 13 is a schematic cross-section of an (Al,Ga,In)N and ZnO direct wafer-bonded LED structure, where the upper part of the (Al,Ga,In)N layer has been grown above random patterned regions.

FIG. 14 is a schematic cross-section of an (Al,Ga,In)N and ZnO direct wafer-bonded LED structure where the ZnO has been patterned before bonding.

FIG. 15 is a schematic cross-section of an (Al,Ga,In)N and ZnO direct wafer-bonded LED structure where the (Al,Ga,In)N has been grown on a patterned substrate.

FIG. 16 is a schematic cross-section of an (Al,Ga,In)N and ZnO direct wafer-bonded LED structure which has been placed in an epoxy environment, eventually incorporating a shaped mirror surrounding the LED.

FIG. 17a is a schematic cross-section of an (Al,Ga,In)N and ZnO direct wafer-bonded LED structure with substrate removed, where the (Al,Ga,In)N has some roughening or structuring such as a photonic crystal, and where electrical contact is ensured at the textured interface by a metal contact pad which is localized or covering the entire interface.

FIG. 17b is a schematic cross-section of an (Al,Ga,In)N and ZnO direct wafer-bonded LED structure with substrate removed, where the (Al,Ga,In)N has some roughening or structuring, and where contact is ensured to the textured interface by a metal layer and through a low index insulating or barrier layer, such as SiO₂ or AlGaN.

FIG. 17c is a schematic cross-section of an (Al,Ga,In)N and ZnO direct wafer-bonded LED structure with substrate removed, where the (Al,Ga,In)N has some roughening or structuring, and where contact is ensured to the textured interface by a metal layer penetrating through vias etched through a low index insulating or barrier layer, such as SiO₂ or AlGaN.

FIG. 18 is a schematic cross-section of an (Al,Ga,In)N and ZnO direct wafer-bonded LED structure with inclusions obtained using LEO or pendeoepitaxy, or by structuring disorder at the bottom of the (Al,Ga,In)N layer, such as a photonic crystal or random patterning, where the substrate has been removed, and contact is made to the (Al,Ga,In)N layer at the bottom of the structure locally or throughout the entire surface.

FIG. 19 is a schematic cross-section of an (Al,Ga,In)N and ZnO direct wafer-bonded LED structure comprising several extracting structures, such as two bonded ZnO pyramids and one, two or three diffracting or randomizing structures.

FIG. 20 is a schematic cross-section of an (Al,Ga,In)N and ZnO direct wafer-bonded LED structure where the embedded photonic crystal is tuned to obtain emission in desired directions.

FIG. 21 is a schematic cross-section of an (Al,Ga,In)N and ZnO direct wafer-bonded LED structure with an embedded photonic crystal, where the (Al,Ga,In)N has been grown over a patterned substrate.

FIG. 22 is a schematic cross-section of an (Al,Ga,In)N and ZnO direct wafer-bonded LED structure, where the ZnO has been patterned before bonding and where a low index layer such as AlGaN has been incorporated in the layer to ensure the existence of a surface guided mode.

FIG. 23 is a schematic cross-section of an (Al,Ga,In)N and ZnO direct wafer-bonded LED structure, where the (Al,Ga,In)N layer has been patterned as a photonic crystal before the ZnO bonding, and where a metallic mirror has been made on the bottom of the substrate.

FIG. 24 is a schematic cross-section of an (Al,Ga,In)N and ZnO direct wafer-bonded LED structure, where the ZnO material is structured in a more complex way such as with multiple pyramids.

FIG. 25 shows a structure of a mega-cone LED in which the optical element (ZnO) is formed on a patterned III-nitride (GaN) mesa.

FIG. 26(A) is a micrograph that shows a top view of a patterned GaN mesa (having triangle patterns in this example), and FIGS. 26(B) and (C) are micrographs that show top views of the resulting fabricated LED, wherein FIG. 26(C) shows the ED under current injection.

FIG. 27a is a schematic cross-section of an (Al,Ga,In)N and ZnO direct wafer-bonded LED structure with the substrate removed, where the n-contact is deposited on the (Al,Ga,In)N layer, the p-contact is deposited on the underside of the ZnO pyramid, and surface patterning is present in the (Al,Ga,In)N layer at the interface with the ZnO pyramid.

FIG. 27b is a micrograph that shows a backside view of the LED structure of FIG. 27a that shows light being emitted from the structure.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The purpose of the present invention is to provide a means of increasing the light extraction efficiency from a light emitting diode (LED) by combining the two methods for light extraction.

The first method is the use of an (Al,In,Ga)N—ZnO structure, where the ZnO is shaped to increase extraction of the light propagating in the ZnO.

The second method addresses the light which is not extracted by the first method because it has remained trapped in the (Al,In,Ga)N thin film layer. This second method is suited for light extraction from thin films, by using surface patterning or texturing, or a photonic crystal acting as a diffraction grating.

A further extension is the general combination of a shaped high refractive index light extraction material with a second light extraction method suited for extraction of light trapped in the (Al,In,Ga)N thin film.

Technical Description

For conciseness throughout this disclosure, “(Al,Ga,In)N layer or thin film” will refer to an ensemble of layers grown by any technique, such as molecular beam epitaxy (MBE), metalorganic chemical vapor deposition (MOCVD) or vapor phase epitaxy (VPE). The ensemble usually comprises a buffer layer grown on a substrate, active layers (quantum wells or quantum dots, barriers, or any other light emitting semiconductor layer), current blocking layers, contact layers, and other layers typically grown for an LED and well known from the state of the art. It is also well known that these layers may be adapted for various specific implementations, using materials other than the (Al,Ga,In)N materials system, and in particular, they may be adapted for each desired wavelength range being emitted from the LED.

An efficient method for enhancing light extraction from an (Al,In,Ga)N LED comprises the use of a shaped ZnO structure bonded to the (Al,In,Ga)N LED. The ZnO structure can act as an efficient contact, notably because of its good electrical characteristics. Moreover, because the ZnO structure is shaped, extraction of the light which propagates inside the ZnO is enhanced.

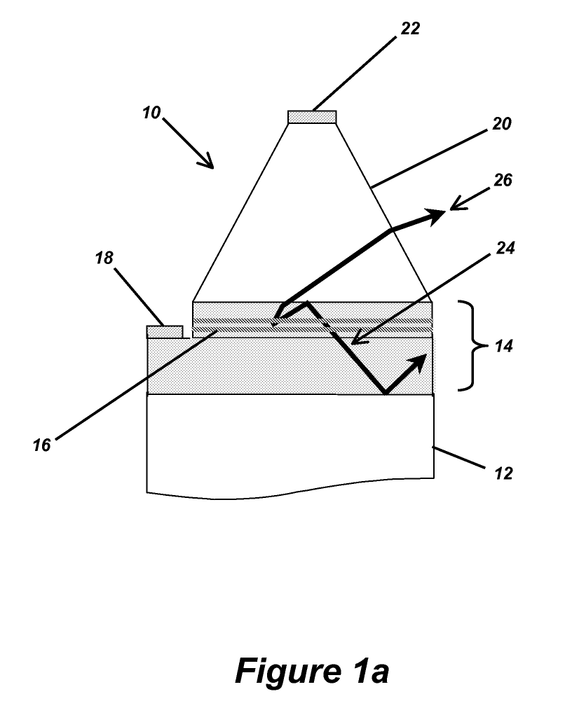

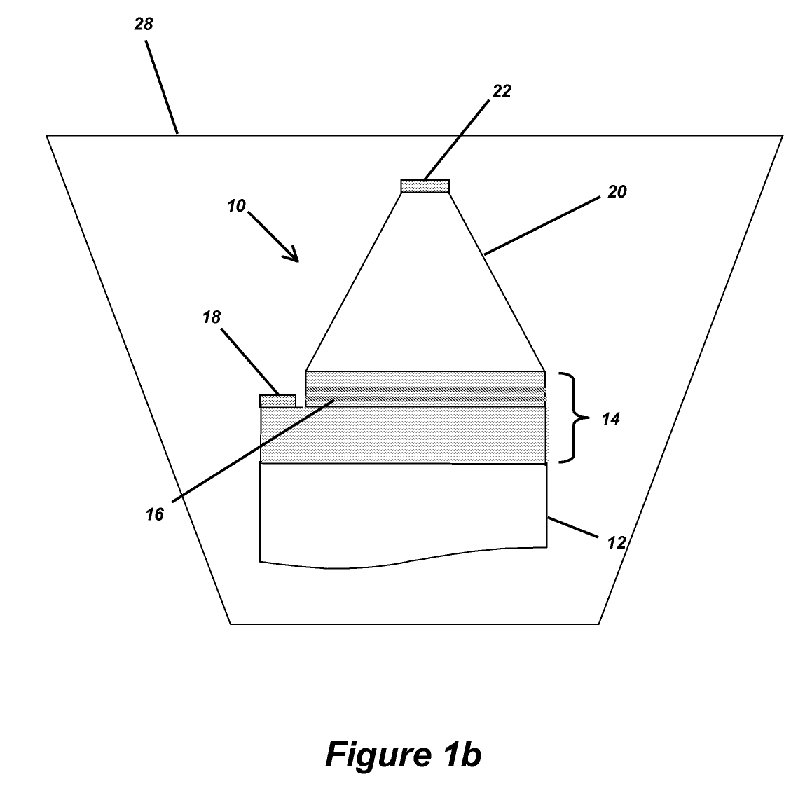

A typical structure implementing this method, where the ZnO structure is shaped into a truncated pyramid is shown in FIG. 1a, which is a schematic cross-section of an (Al,Ga,In)N and ZnO direct wafer-bonded LED structure 10 that includes a substrate 12, (Al,In,Ga)N layer(s) 14, an active region or light emitting species within the (Al,In,Ga)N layer(s) 14 such as quantum wells 16, contact 18, ZnO pyramid 20 and contact 22, wherein arrow 24 represents guided mode light emissions and arrow 26 represents extracted light emissions.

This structure is described in the disclosure of U.S. Utility application Ser. No. 11/593,268, filed on Nov. 6, 2006, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-U1 (2006-271-2), which application claims the benefit under 35 U.S.C. Section 119(e) of U.S. Provisional Application Ser. No. 60/734,040, filed on Nov. 4, 2005, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-P1 (2006-271-1), both which applications are incorporated by reference herein.

An improvement over the FIG. 1a method comprises combining, or embedding the structure in a light extracting structure such as a tapered lens, so that most light entering the lens lies within the critical angle and is extracted, as described in the above mentioned U.S. Utility and Provisional Applications and illustrated in FIG. 1a, wherein the LED structure 10 is combined with, or embedded in, a shaped light extractor 28, such as a plastic lens.

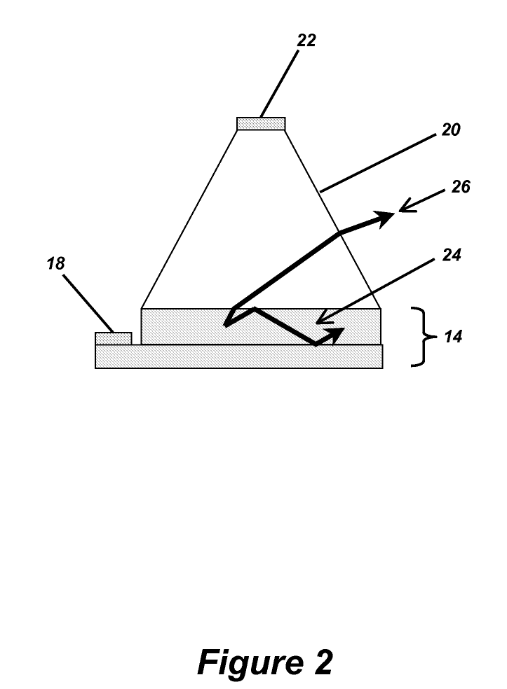

In some cases, the original substrate 12 may be removed, as shown in FIG. 2.

However, part of the light emitted by the LED is not extracted because it remains trapped in the (Al,In,Ga)N thin film and does not propagate in the ZnO. This light is referred to as guided light 24. This trapped light results from the fact that the refractive index of ZnO is lower than the refractive index of the (Al,In,Ga)N region. Typically, 40% to 50% of the total light emitted by the LED remains trapped in this way.

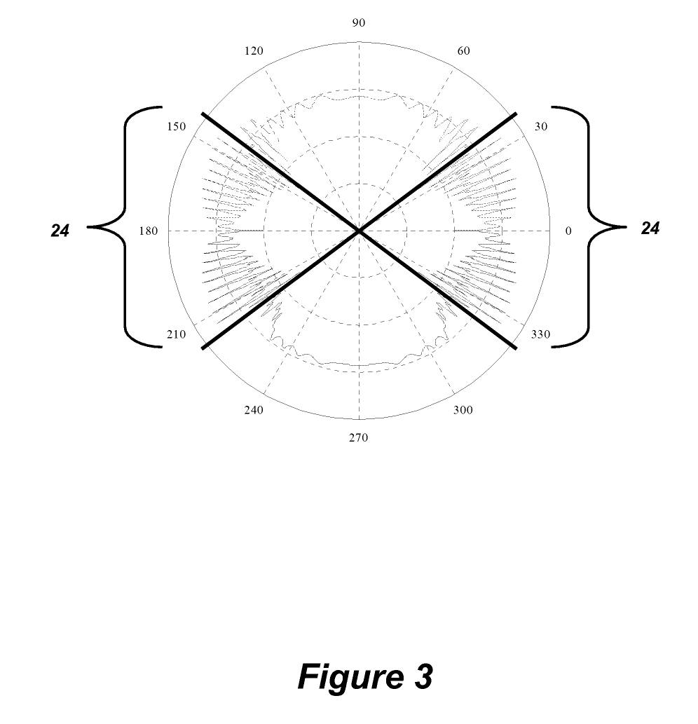

FIG. 3 shows the dipole emission representing the light emitted by a quantum well in a structure made of a 2 micron thick (Al,In,Ga)N layer sandwiched between ZnO and sapphire. In FIG. 3, the light 24 emitted between the thick black lines corresponds to guided light 24 and amounts to 45% of the total emitted light. The present invention aims at extracting light emitted at small incidence angles and being guided due to total internal reflection at the semiconductor-air interface.

In order to also extract the guided light, the (Al,In,Ga)N—ZnO structure is combined with another additional light extractor localized in, adjacent or in close proximity to, the (Al,In,Ga)N thin film, wherein the additional light extractor is efficient at extracting the light trapped in the (Al,In,Ga)N thin film.

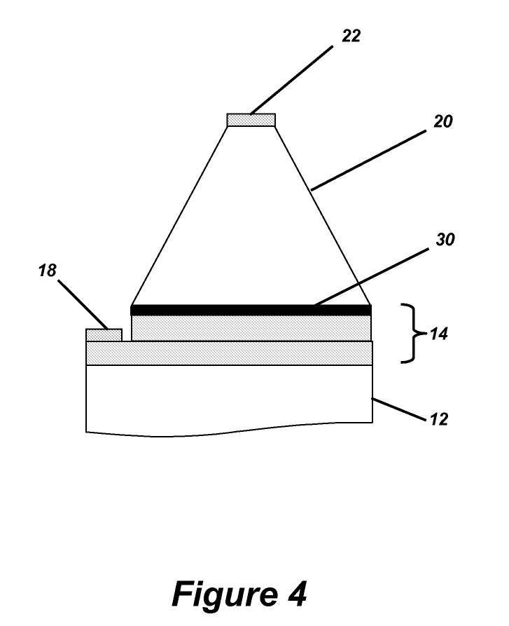

FIG. 4 represents a general embodiment of an optoelectronic device combining both light extraction methods, where the ZnO pyramid is a first extractor 20 comprising a shaped optical element structure, positioned adjacent the (Al,Ga,In)N layers 14, i.e., grown on or bonded to the (Al,In,Ga)N layers 14, for extracting at least a portion of the light emitted from the (Al,Ga,In)N layers 14, and the black region symbolizes a second light extractor 30, in proximity to the (Al,Ga,In)N layers 14 and the first light extractor 20, for extracting additional light, such as guided light, from the (Al,Ga,In)N layers 14 that has not been extracted by the first light extractor 20.

The second light extractor 30 may comprise a modification of either a top or bottom interface of the (Al,In,Ga)N layers 14, or a modification within the (Al,In,Ga)N layers 14, that increases light extraction. This modification may comprise a surface patterning or texturing of one or both surfaces of the (Al,In,Ga)N thin film 14, wherein the patterning or texturing can be ordered or random.

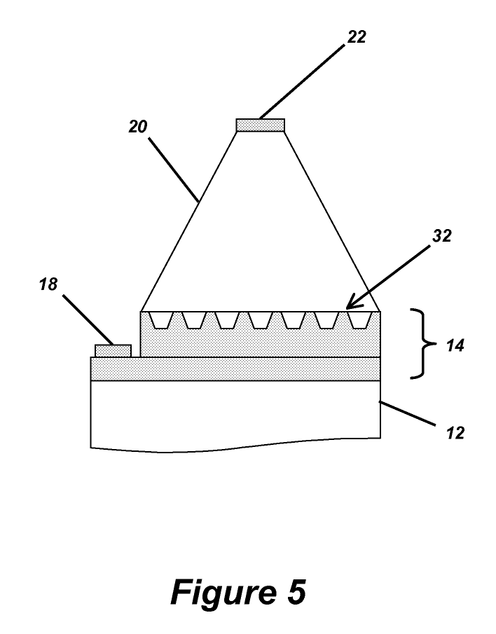

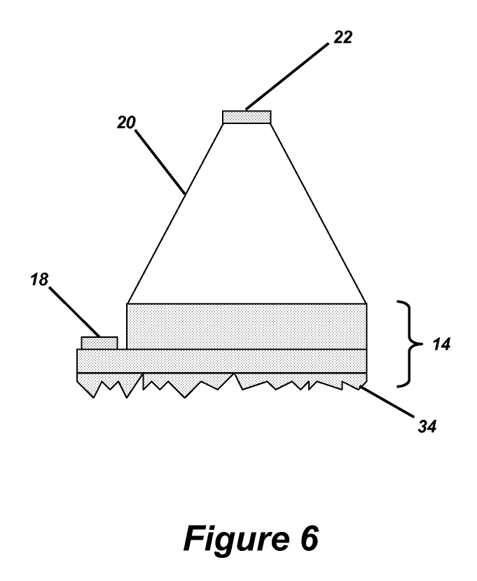

FIG. 5 represents an embodiment of the invention where a surface patterning 32 is formed on the front (or top surface) of the (Al,In,Ga)N layer 14, and FIG. 6 is another embodiment where a random surface texture 34 is formed on the back (or bottom surface) of the (Al,In,Ga)N layer 14 after the initial substrate 12 has been removed. In both cases shown in FIGS. 5 and 6, the surface texturing provides more trajectories for the guided light, increasing the guided light's extraction.

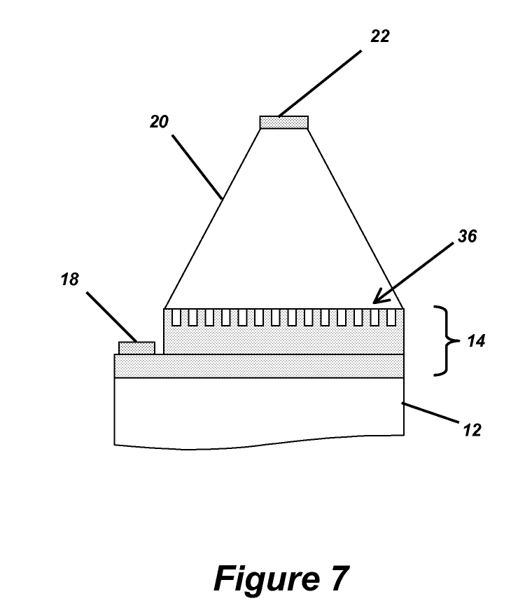

In yet another embodiment, shown in FIG. 7, the modification that comprises the second light extractor may be an ordered structuring, such as a photonic crystal 36 acting as a diffraction grating. The photonic crystal 36 turns guided light into radiative light which can escape the structure, hence enhancing light extraction.

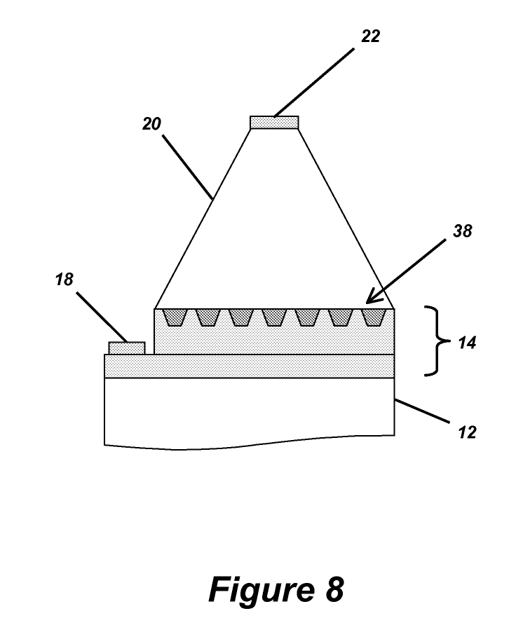

In general, whether using a patterning, texturing or a photonic crystal, the holes formed by the modification of the surface may contain air, or may be filled with another material such as a dielectric, a metal, or another light-emitting material such as phosphors. FIG. 8 represents an embodiment of the invention where an ordered surface patterning 38 is filled with phosphors. The light captured by the phosphor is re-emitted at a different wavelength, thus yielding multicolor emission with high extraction efficiency because of the structured surface 38 (second extraction method) and pyramid 20 (first extraction method). The multi-color emission may eventually appear as white light.

As noted above, the second light extraction method may also comprise a modification of the (Al,In,Ga)N layer 14 structure itself, rather than its surface. For example, the second light extractor may be embedded inside the (Al,In,Ga)N layer 14. For instance, the second light extractor may be a photonic crystal embedded inside the (Al,In,Ga)N layer 14, having the same effect as the FIG. 7 embodiment. Thus, the light emitting species 16 within the (Al,In,Ga)N layer 14 structure may be positioned below, within or above the second light extractor.

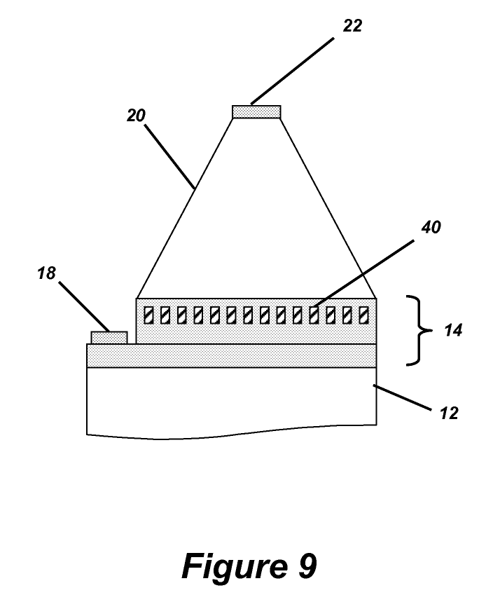

A second light extractor embedded inside the (Al,In,Ga)N layer 14, such as a buried photonic crystal, may be formed by different methods. In one embodiment of the invention, the photonic crystal 40 is formed by overgrowing (Al,In,Ga)N 14 over a Lateral Epitaxial Overgrowth (LEO) mask (where the LEO mask is silicon dioxide SiO₂, for example). In this case, the LEO mask also serves as a photonic crystal 40, due to its index contrast with the (Al,In,Ga)N material, as illustrated in FIG. 9 and described in U.S. Utility application Ser. No. 11/067,910, filed Feb. 28, 2005, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-1), which application is incorporated by reference herein.

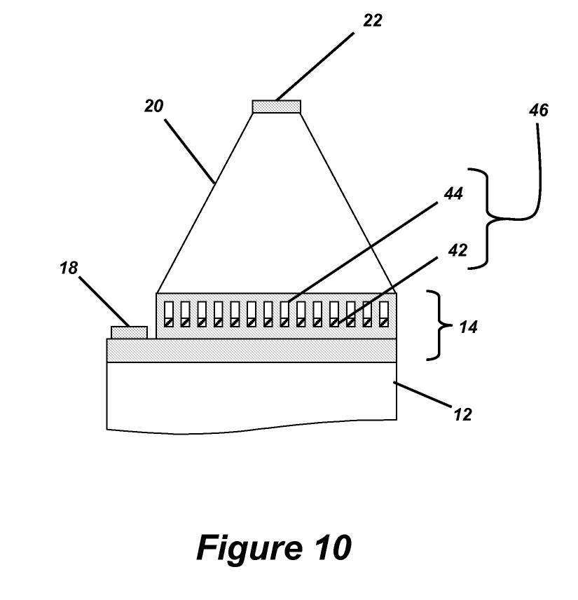

In another embodiment, shown in FIG. 10, the regrowth does not entirely cover the LEO mask 42, and air regions 44 are present above the LEO mask 42. In this case, the photonic crystal effect 46 is also due to the index contrast between the air 44 and the (Al,In,Ga)N material 14.

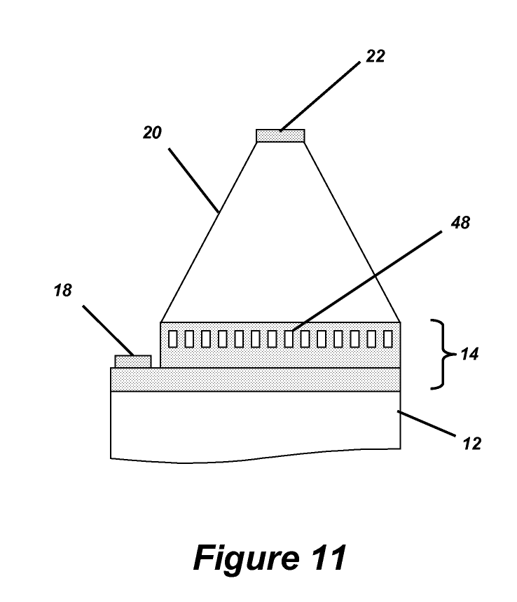

In a third embodiment, part of the (Al,In,Ga)N layer 14 is grown and a photonic crystal 48 is formed at a surface of the (Al,In,Ga)N layer 14, for instance by nano-imprint and dry etching. The (Al,In,Ga)N 14 is then regrown on top of the photonic crystal 48 structure, so that the photonic crystal 48 is embedded in a final (Al,In,Ga)N 14 structure, as illustrated in FIG. 11.

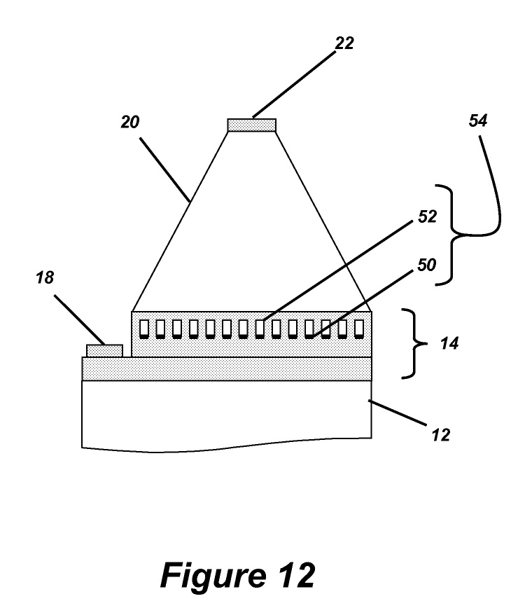

In yet another embodiment, part of the (Al,In,Ga)N layer 14 is grown, and part of the surface of the (Al,In,Ga)N layer 14 is altered 50, by ion implantation, for example. The (Al,In,Ga)N 14 is then regrown on top of this structure 50, but regrowth does not occur above 52 the altered parts 50 of the surface, thereby forming a photonic crystal 54, as shown in FIG. 12.

In all of these embodiments, the active layer may be located either below, above or inside the photonic crystal region. These embodiments may also be combined with a fabrication step to enhance or restore the (Al,In,Ga)N material quality after formation of the photonic crystal region, using, for example, a thermal annealing step.

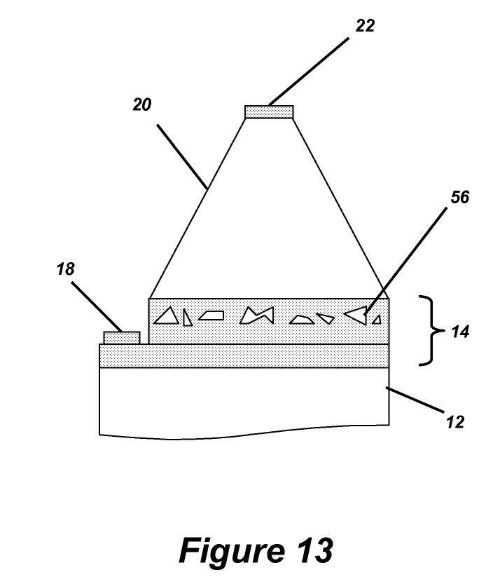

In another embodiment, the embedded photonic crystal is replaced by an embedded pattern 56, wherein the pattern 56 may be either ordered or random, thereby providing more trajectories for the guided light and increasing the guided light extraction, as shown in FIG. 13. Again, the pattern 56 may be formed by a variety of methods, such as LEO, regrowth on a photonic crystal etched in GaN, or regrowth on an altered GaN surface. FIG. 13 represents an embodiment of the invention where a random texture 56 is embedded in the (Al,In,Ga)N layer 14.

For embodiments described in FIGS. 9-13, the layers containing light emitting species can be placed below, within or above the structured layers comprising the second light extractor.

The second light extractor may also comprise a modification of either a top or bottom interface of the first light extractor 20, or a modification within the first light extractor 20, wherein the modification comprises a pattern, a texture, or a photonic crystal.

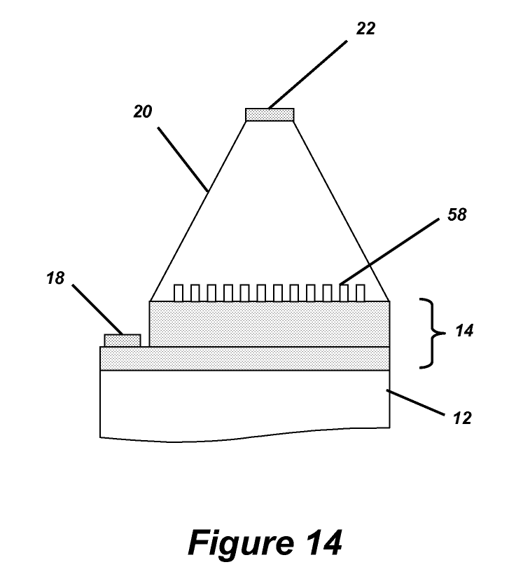

For example, the second light extractor 58 may also be formed in the ZnO structure 20, close to the interface with the (Al,In,Ga)N layer 14, as shown in FIG. 14. Again, the second light extractor 58 may comprise a patterning or texturing (either ordered or random) of the ZnO 20 surface bonded to the (Al,In,Ga)N layer 14, or may comprise the formation of a photonic diffraction grating on the ZnO 20 surface. In this case, extraction of the guided light occurs because the guided light leaks in the ZnO 20 region over a short scale, and is therefore sensitive to the geometry of the ZnO 20 close to the interface with the (Al,In,Ga)N layer 14. FIG. 14 represents an embodiment of the invention where a photonic crystal 58 is formed in the ZnO 20 region (for example, on the Zinc surface) at the bonded interface.

In addition, the second light extractor may comprise a modification of either a top or bottom interface of a substrate 12 supporting the (Al,In,Ga)N layers 14, or a modification within the substrate 12, wherein the modification comprises a pattern, a texture, or a photonic crystal.

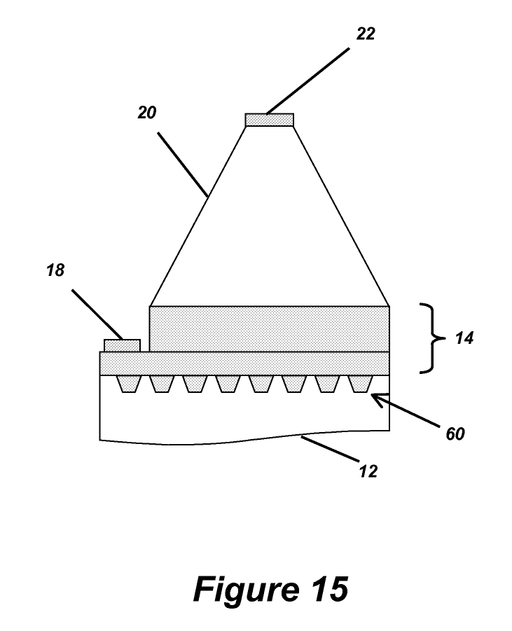

For example, the second light extractor 60 may be formed in the substrate 12, at the interface with the (Al,In,Ga)N layer 14, as shown in FIG. 15. In this embodiment, the second light extractor 60 is an ordered patterning is formed on the surface of the substrate, or in the substrate 12, and the (Al,In,Ga)N layer 14 is subsequently grown on top of this patterning. Again, the second light extractor 60 may comprise a patterning or texturing (either ordered or random) of the substrate 12, or comprise the formation of a photonic diffraction grating on the substrate 12 surface. In this case, extraction of the guided light occurs because the guided light leaks in the substrate 12 region over a short scale, and is therefore sensitive to the geometry of the substrate 12 close to the interface with the (Al,In,Ga)N layer 14.

In all these embodiments, the light which propagates in the ZnO 20 is efficiently extracted by the ZnO 20 shaping of the first extraction method, and the guided light is efficiently extracted by the second light extraction method, so that most of the emitted light is extracted.

Possible Modifications

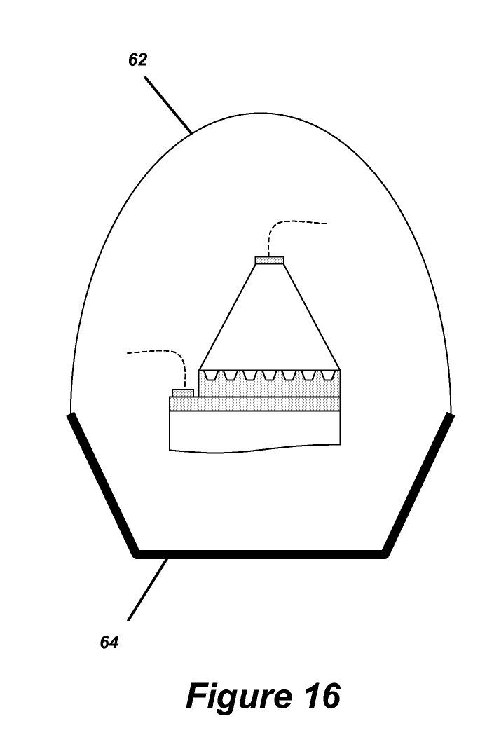

The entire device structure may be combined, embedded or placed within a light extracting structure, e.g., a shaped high refractive index light extraction material, for extracting even more light from the (Al,Ga,In)N layers. For example, FIG. 16 shows the entire device structure placed in an environment comprising an epoxy dome 62 that resides on a holder 64 structure, which provides for robustness and increased light extraction. This environment may be shaped for optimal light extraction.

Moreover, the environment and/or the ZnO structure may contain light emitting species, which perform wavelength conversion for the light emitted by the (Al,Ga,In)N layer, thus providing new emitted wavelengths, which, for instance, may be used to achieve overall white light emission.

The ZnO structure can be replaced by another material having similar characteristics, namely good transmission properties, high refractive index for efficient light extraction and good electrical properties. For example, this material can be Silicon Carbide (SiC) or Indium Tin Oxide (ITO).

The original substrate on which the (Al,In,Ga)N layer was grown may be removed, for example by laser lift-off, dry etching or chemical etching. After the (Al,In,Ga)N layer has been removed from the substrate, the (Al,In,Ga)N may be further modified. The (Al,In,Ga)N may be thinned down, and a second light extractor region may be formed on top of the new (Al,In,Ga)N surface.

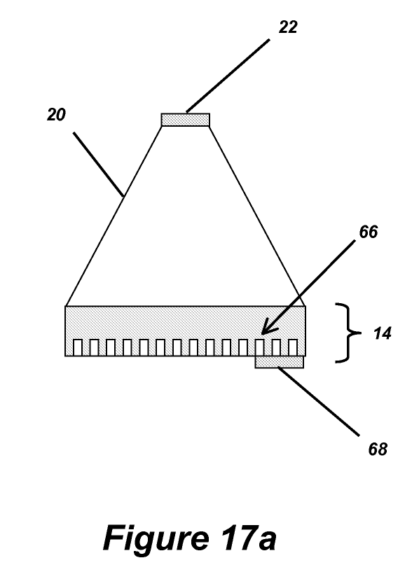

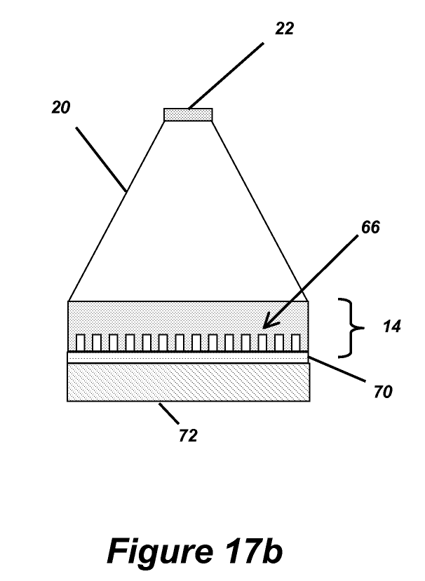

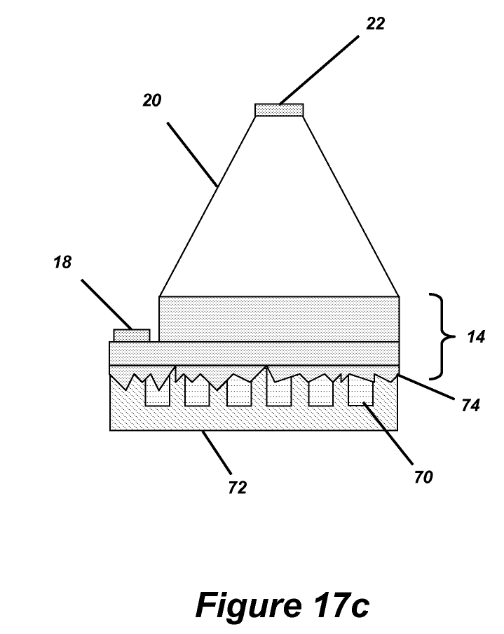

FIG. 17a represents an embodiment of the invention where the substrate upon which the (Al,In,Ga)N layers 14 reside is removed and a photonic crystal 66 is formed on the resulting exposed surface of the (Al,In,Ga)N layers 14. In addition, a bottom electrical contact 68 may be formed on part or all of the resulting exposed surface of the (Al,In,Ga)N layers 14.

In order to diminish absorption of the guided light, it may prove advantageous to put a low index layer 70 (such as AlGaN or SiO₂) between the resulting exposed surface of the (Al,In,Ga)N layers 14 and a metallic contact 72, as shown in FIG. 17b.

FIG. 17c illustrates an embodiment that diminishes contact resistance between the metallic contact 72 (acting as a mirror) and the resulting exposed surface of the (Al,In,Ga)N layers 14, while maintaining low waveguide optical loss. In this embodiment, the low index layer 70 is patterned, textured or etched with via holes, which then may be filled with metal.

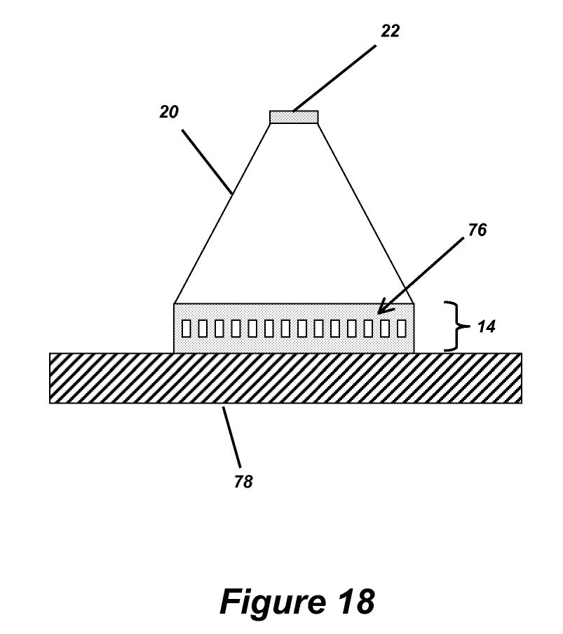

In addition, the resulting surface of the (Al,In,Ga)N layers 14, as well as the case with embedded structuring such as photonic crystals 76, may also be bonded to another substrate 78, such as a metallic substrate acting as a substrate, as shown in FIG. 18.

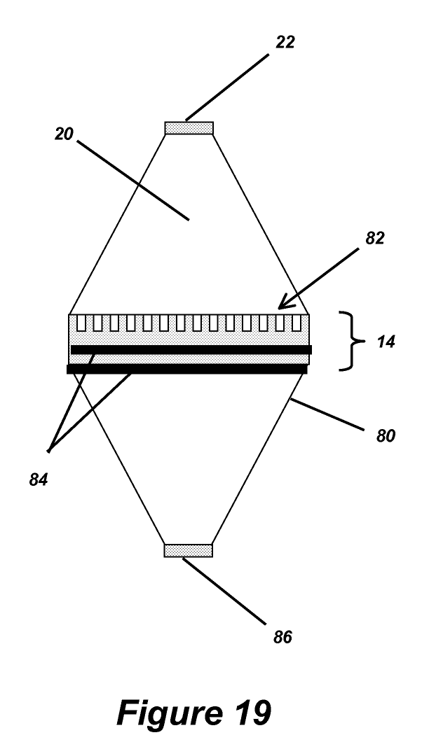

A second optical element, such as a second ZnO structure 80, may be formed on the second light extractor, as shown in FIG. 19. This can provide for efficient current injection on both sides of the LED. The second ZnO structure 80 may be associated with one or more embedded diffraction layers 82, 84, as described previously, such as, for example, random patterns or photonic crystals, and may include another contact 86.

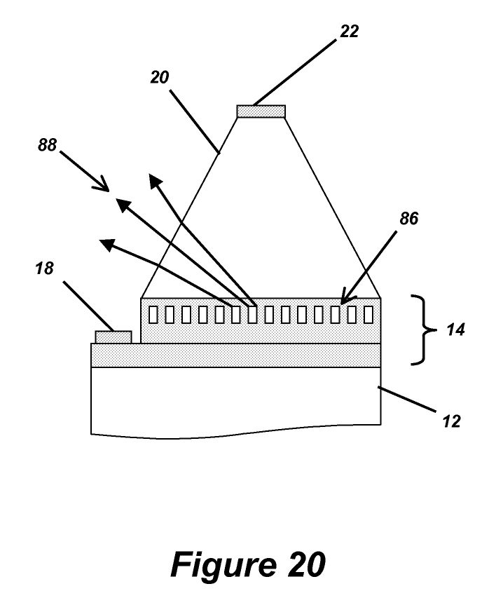

The light extraction methods may be combined to obtain specific far-field patterns having increased directionality in certain directions. In the case where the second light extraction method is a photonic crystal grating 86, the second light extractor can be designed so that light extraction 88 occurs at or around specific angles where reflection at the ZnO 20 interface is minimized, as depicted in FIG. 20.

The shape, size and other parameters (such as crystal parameters in the case of a photonic crystal) of the second light extractor may be varied along the structure in order to provide position-dependent light extraction behavior.

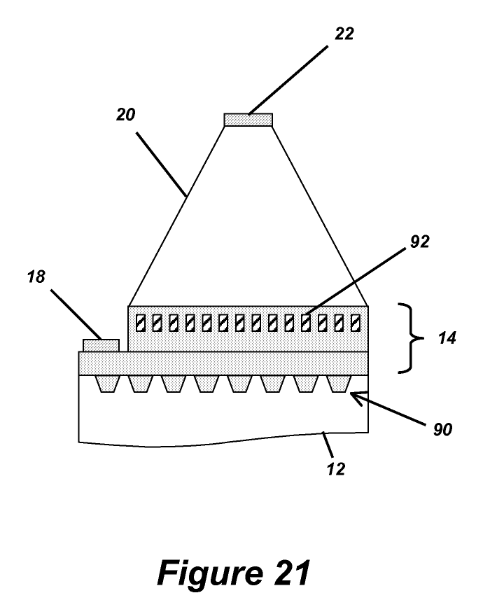

Several second light extractors may be combined, such as a combination of random patterns, ordered patterns and photonic crystals. FIG. 21 shows an embodiment of the invention where an ordered pattern 90 is formed on the substrate 12, part of the (Al,In,Ga)N layer 14 is grown, a LEO mask 92 is formed, and the rest of the (Al,In,Ga)N layer 14 is grown over the LEO mask 90.

The (Al,Ga,In)N epitaxial structure may contain layers which provide refractive index modulation, such as Distributed Bragg Reflectors (DBRs) or optical barriers as described in U.S. Utility application Ser. No. 11/067,956, filed Feb. 28, 2005, by Aurelien J. F. David, Claude C. A Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1), which application is incorporated by reference herein.

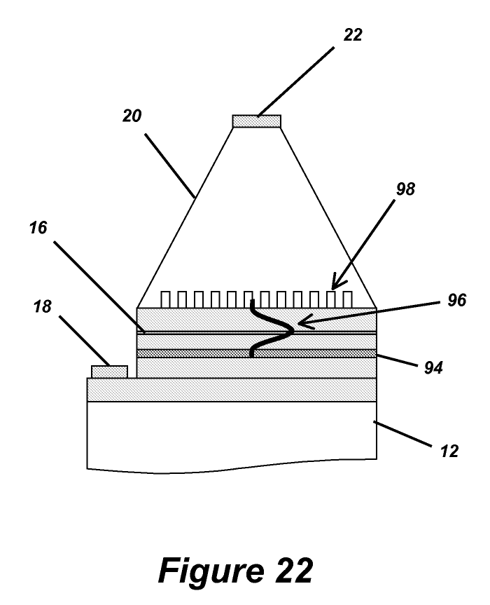

These modulation layers may modify the light extraction properties of the structure or modify the distribution of guided light, therefore making the second light extractor even more efficient at extracting guided light. FIG. 22 shows an implementation of such a structure, where an optical confinement layer 94 or optical barrier (made from a material of lower refractive index) creates a so-called “surface” guided mode 96 in the vicinity of a photonic crystal 98 formed in the ZnO structure 20. Such a mode 96 is then efficiently extracted by the photonic crystal 98 formed in the ZnO structure 20.

A material may be added at the interface between the (Al,In,Ga)N layer and the ZnO structure, such as a thin metallic layer. This may be used to enhance the properties of the electric contact.

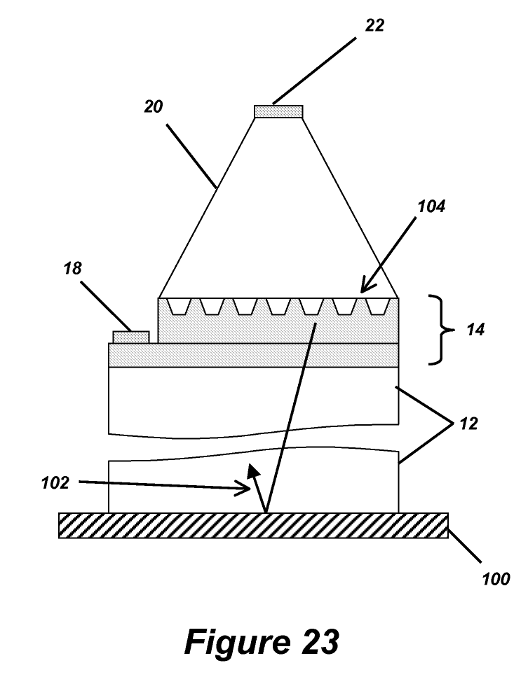

Metallic or dielectric mirrors 100 may be placed around the structure, for example, below the substrate 12, or replacing the substrate 12, or on some sides of the ZnO structure 20, to redirect light in certain directions, including light extracted by patterning 104, as shown in FIG. 23.

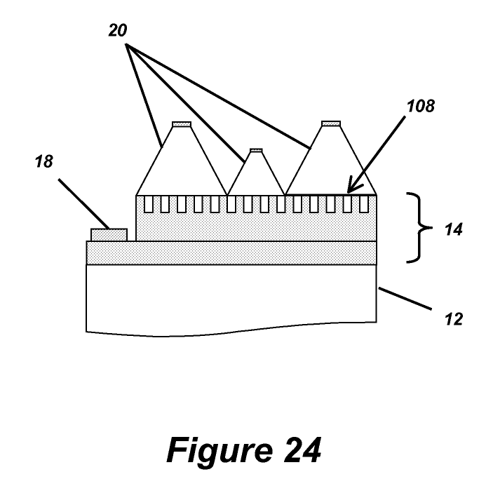

The ZnO structure may have a complex surface, such as a pyramid with roughened facets, or an ensemble of pyramids. FIG. 24 shows a structure where several ZnO pyramids 20 reside on top of a photonic crystal 108.

The ZnO can be replaced by any transparent high index material, such as metal oxides. The shaped transparent high index material (such as ZnO) can be attached using, for example, wafer bonding, glue bonding, sputtering, epitaxial growth, adhesion bonding or e-beam evaporation.

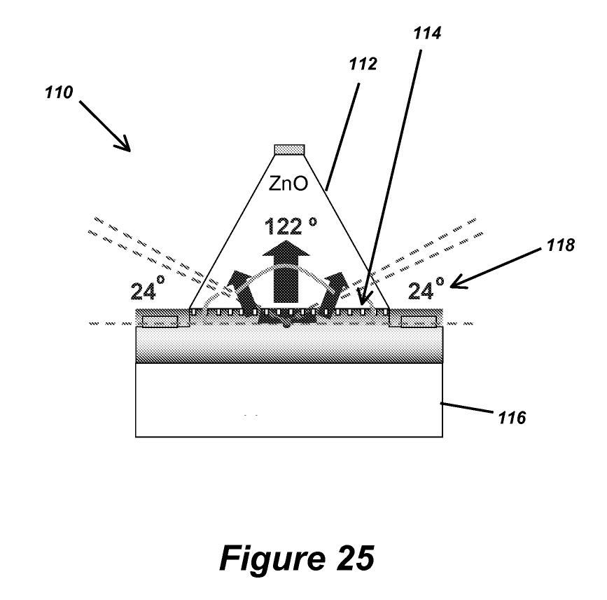

FIG. 25 shows an embodiment of the present invention, wherein the optoelectronic device comprises a mega-cone LED 110, in which a ZnO optical element 112, comprised of a high refractive index material, is grown or bonded on a top surface of a patterned III-nitride (GaN) mesa 114, which is comprised of one or more III-nitride layers and includes an active layer comprising light emitting species, that is formed on a substrate 116. This structure, and specifically, the patterned mesa 114, enables light of low angle incidence 118 to enter the ZnO optical element 112 more efficiently, so that almost all of the light can enter the ZnO optical element 112, in order to obtain more optical output power. On the other hand, absent such patterning of the GaN mesa 114, low angle incidence light 118 cannot enter the ZnO optical element 112 as efficiently, because of the difference in the optical index of refraction between the GaN (n=2.4) and ZnO (n=2.1).

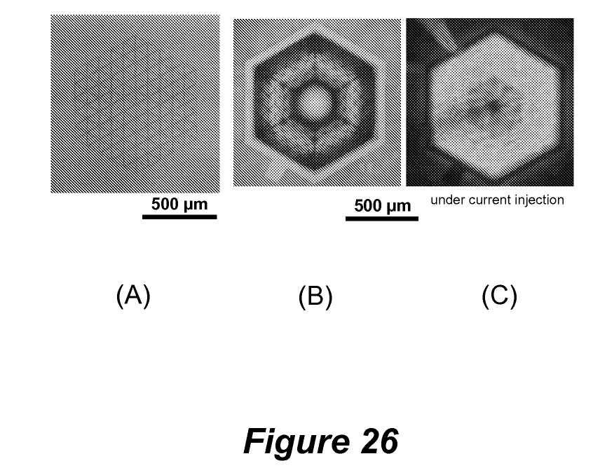

FIG. 26(A) is a micrograph that shows a top view of a patterned GaN mesa (having triangle patterns, in this example), and FIGS. 26(B) and 26(C) are micrographs that show top views of the resulting fabricated LED, wherein FIG. 26(C) shows the LED under current injection.

These structures provide improved power output as described in the following table:

| Structure | Output power |
|---|---|
| Patterned mesa | 15.9 mW |
| Flat mesa | 14.7 mW |

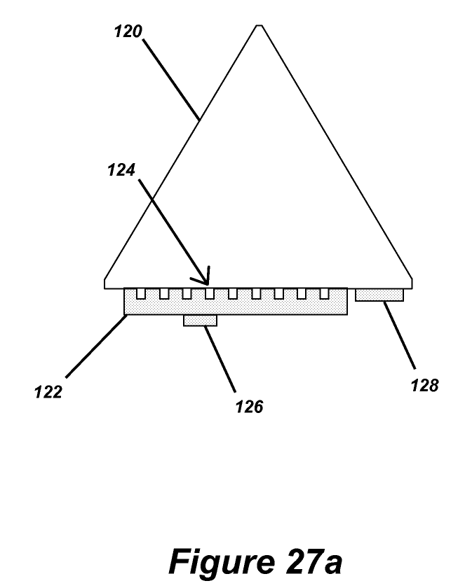

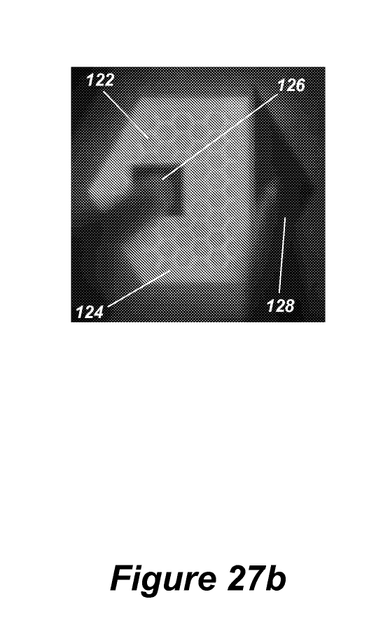

FIG. 27a is a schematic cross-section of an (Al,Ga,In)N and ZnO direct wafer-bonded LED structure with the substrate removed, where the shaped optical element is a ZnO pyramid 120, the (Al,Ga,In)N layer 122 is patterned 124 at the interface with the ZnO pyramid 120, the n-contact 126 is deposited on the (Al,Ga,In)N layer 122, and the p-contact 128 is deposited on the underside of the ZnO pyramid 120. It can be seen that this structure enhances light extraction, because the p-contact 128 is moved from the top of the ZnO pyramid 120 to the bottom of the ZnO pyramid 120. A p-contact on the top of the ZnO pyramid would be expected to decrease light extraction.

FIG. 27b is a micrograph that shows a backside view of the LED structure of FIG. 27a that indicates the (Al,Ga,In)N layer 122, the patterning 124 of the interface of the (Al, Ga, In)N layer 122 with the ZnO pyramid 120, the n-contact 126 deposited on the (Al,Ga,In)N layer 122, and the p-contact 128 deposited on the underside of the ZnO pyramid 120. This micrograph also shows light being emitted from the structure. It can be seen that the patterning 124 emits light effectively.

### REFERENCES

The following references are incorporated by reference herein:
[1] U.S. Pat. No. 6,538,371, issued Mar. 25, 2003, to Duggal et al., and entitled “White Light Illumination System.”
[2] U.S. Pat. No. 6,525,464, issued Feb. 25, 2003, to Y-C. Chin, and entitled “Stacked Light-Mixing LED.”
[3] U.S. Pat. No. 6,504,180, issued Jan. 7, 2003, Heremans et al., and entitled “Method of Manufacturing Surface Textured High Efficiency Radiating Devices And Devices Obtained Therefrom.”
[4] U.S. Pat. No. 6,163,038, issued Dec. 19, 2000 to Chen et al., and entitled “White Light Emitting Diode and Method of Manufacturing the Same.”
[5] U.S. Pat. No. 5,779,924, issued Jul. 14, 1998, to Krames et al., and entitled “Ordered Interface Texturing For a Light Emitting Device.”
[6] U.S. Pat. No. 5,362,977, issued Nov. 8, 1994, to Hunt et al., and entitled “Single Mirror Light Emitting Diodes with Enhanced Intensity.”
[7] U.S. Pat. No. 5,226,053, issued Jul. 6, 1993, to Cho et al., and entitled “Light Emitting Diode.”
[8] M. R. Krames et al., “High-power truncated-inverted-pyramid (AlₓGa₁₋ₓ)_{0.5}In_{0.5}P/GaP light-emitting diodes exhibiting greater than 50% external quantum efficiency,” Applied physics letters vol. 75, pp. 2365-2367, (1999).
[9] W. Schmid and J. R. Eberhard F., King R., Miller M., Joos M. and K. J. Ebeling, “45% Quantum Efficiency Light-Emitting-Diodes with Radial Outcoupling Taper,” presented at SPIE, San Jose, Calif., (2000).
[10] I. Schnitzer et al., “30% External Quantum Efficiency from Surface Textured, Thin-Film Light-Emitting-Diodes,” Applied Physics Letters vol. 63, pp. 2174-2176, (1993).
[11] T. Fujii et al., “Cone-shaped surface GaN-based light-emitting diodes,” Physica Status Solidi C, no. 7, pp. 2836-40 (2005).
[12] Z. H. Feng and K. M Lau, “Enhanced luminescence from GaN-based blue LEDs grown on grooved sapphire substrates,” IEEE Photonics Technology Letters, vol. 17, no. 9, pp. 1812-14 (September 2005).
[13] T. Gessmann et al., “Light-emitting diodes with integrated omnidirectionally reflective contacts,” Proceedings of the SPIE, vol. 5366, no. 1, 2004, pp. 53-61.
[14] R. Windisch et al., “InGaAlP thin film LEDs with high luminous efficiency,” Proceedings of the SPIE, vol. 5 366, no. 1, pp. 43-52 (2004).
[15] Y. C. Shen et al., “Optical cavity effects in InGaN/GaN quantum-well-heterostructure flip-chip light-emitting diodes,” Proceedings of the SPIE, vol. 5366, no. 1, pp. 20-25 (2004)
[16] R. Joray et al., “High efficiency planar MCLEDs,” Physica Status Solidi B, vol. 242, pp. 2315-25, (2005)
[17] C. Weisbuch et al, “Recent results and latest views on microcavity LEDs,” Proceedings of the SPIE, vol. 5366, no. 1, pp. 1-19 (2004)
[18] A. David et al., “Photonic crystal laser lift-off GaN light-emitting diodes,” Applied Physics Letters, vol. 88, pp. 133514-1-3 (2006).
[19] R. Davis et al., “Pendeo-epitaxy-A new approach for lateral growth of gallium nitride films,” MRS Internet Journal Nitride Research 6, p. 14, (2001).
[20] T. M. Katona, J. S. Speck and S. P. DenBaars, “Effect of the nucleation layer on stress during cantilever epitaxy of GaN on Si (111),” Physical Status Solidi A, 194, pp. 541-544, (2002).
[21] Isao Kidoguchi, Akihiko Ishibashi, Gaku Sugahara, and Yuzaburoh Ban, “Air-bridged lateral epitaxial overgrowth of GaN thin films,” Applied Physics Letters 76, pp. 3768-3770 (2000).
[22] B. Beaumont, P. Vennegues, P. Gibart, “Epitaxial Lateral Overgrowth of GaN,” Physica Status Solidi (b) 227, 1-43 (2001).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
(a) a substrate;
(b) an active layer comprising light emitting species;
(c) a patterned mesa formed on the active layer; and
(d) an optical element grown or bonded on a top surface of the patterned mesa.

2. The device of claim 1, wherein the patterned mesa is comprised of one or more III-nitride layers.

3. The device of claim 1, wherein the patterned mesa enables light of low angle incidence to enter the optical element more efficiently, in order to obtain more optical output power.

4. The device of claim 1, wherein the optical element comprises a high refractive index material.

5. An optoelectronic device, comprising:
(a) one or more (Al,Ga,In)N layers including light emitting species;
(b) a first light extractor, comprising a shaped optical element, adjacent the (Al,Ga,In)N layers, for extracting at least a portion of the light emitted from the (Al,Ga,In)N layers; and
(c) a second light extractor, in proximity to the (Al,Ga,In)N layers and the first light extractor, for extracting additional light from the (Al,Ga,In)N layers that has not been extracted by the first light extractor.

6. The device of claim 5, wherein the first light extractor comprises a shaped structure grown on or bonded to the (Al,In,Ga)N layers.

7. The device of claim 5, wherein the second light extractor comprises a modification of either a top or bottom interface of the (Al,In,Ga)N layers or a modification within the (Al,In,Ga)N layers, and the modification comprises a pattern, a texture, or a photonic crystal.

8. The device of claim 7, wherein holes formed by the modification contain air, a dielectric, a metal, or a light-emitting material.

9. The device of claim 5, wherein the light emitting species are positioned below, within or above the second light extractor.

10. The device of claim 5, wherein the second light extractor comprises a modification of either a top or bottom interface of the first light extractor or a modification within the first light extractor, and the modification comprises a pattern, a texture, or a photonic crystal.

11. The device of claim 5, wherein the second light extractor comprises a modification of either a top or bottom interface of a substrate supporting the (Al,In,Ga)N layers or a modification within the substrate, and the modification comprises a pattern, a texture, or a photonic crystal.

12. The device of claim 5, further comprising a shaped high refractive index light extraction material for extracting even more light from the (Al,Ga,In)N layers.

13. The device of claim 5, further comprising combining or embedding the device in a light extracting structure.

14. The device of claim 13, wherein the light extracting structure contains light emitting species, which perform wavelength conversion for the light emitted by the (Al,Ga,In)N layers.

15. The device of claim 5, further comprising a substrate upon which the (Al,In,Ga)N layers reside, wherein the substrate is removed and a photonic crystal is formed on a resulting exposed surface of the (Al,In,Ga)N layers.

16. The device of claim 15, further comprising an electrical contact formed on the resulting exposed surface of the (Al,In,Ga)N layers.

17. The device of claim 16, further comprising a low index layer positioned between the resulting surface of the (Al,In,Ga)N layers and the contact, in order to diminish absorption of guided light.

18. The device of claim 17, wherein the low index layer is patterned, textured or etched with holes to diminish contact resistance between the contact and the resulting surface of the (Al,In,Ga)N layers, while maintaining low waveguide optical loss.

19. The device of claim 15, wherein the resulting surface of the (Al,In,Ga)N layers is bonded to another substrate.

20. The device of claim 5, further comprising a second optical element formed on the second light extractor.

21. A method of fabricating an optoelectronic device, comprising:
(a) providing a substrate;
(b) forming an active layer including light emitting species on the substrate;
(c) forming a patterned mesa formed on the active layer; and
(d) growing or bonding an optical element on a top surface of the patterned mesa.

22. The method of claim 21, wherein the patterned mesa is comprised of one or more III-nitride layers.

23. The method of claim 21, wherein the patterned mesa enables light of low angle incidence to enter the optical element more efficiently, in order to obtain more optical output power.

24. The method of claim 21, wherein the optical element comprises a high refractive index material.

25. A method of fabricating an optoelectronic device, comprising:
(a) forming one or more (Al,Ga,In)N layers including light emitting species;
(b) creating a first light extractor, comprising a shaped optical element adjacent the (Al,Ga,In)N layers, for extracting at least a portion of the light emitted from the (Al,Ga,In)N layers; and
(c) creating a second light extractor, in proximity to the (Al,Ga,In)N layers and the first light extractor, for extracting additional light from the (Al,Ga,In)N layers that has not been extracted by the first light extractor.
